(19) United States
(12) Patent Application Publication
(10) Pub. No.: US 2023/0349037 A1
(43) Pub. Date: Nov. 2, 2023

(54) METAL MASK AND METHOD FOR MANUFACTURING METAL MASK

(71) Applicant: Dai Nippon Printing Co., Ltd., Tokyo (JP)

(72) Inventor: Yuji ANZAI, Tokyo (JP)

(73) Assignee: Dai Nippon Printing Co., Ltd., Tokyo (JP)

(21) Appl. No.: 18/187,159

(22) Filed: Mar. 21, 2023

(30) Foreign Application Priority Data
Mar. 31, 2022 (JP) 2022-058423

(51) Int. Cl. C23C 16/04

(52) U.S. Cl. CPC C23C 16/042

(57) ABSTRACT

A metal mask in which deformation and breakage are less likely to occur at a boundary portion, and a method for manufacturing the metal mask are provided. The metal mask includes an effective region, a peripheral region, and a dummy region. The effective region includes a first through-hole and a first top part. The first top part has a height H1. The peripheral region is positioned around the effective region. The dummy region is positioned between the effective region and the peripheral region. The dummy region includes a second top part. The second top part has a height H2. The height H2 is greater than the height H1.

### BACKGROUND OF THE INVENTION

### Field of the Invention

The present disclosure relates to a metal mask and a method for manufacturing the metal mask.

### Description of the Related Art

Pixels of an organic EL display device are formed by causing a material for forming pixels to adhere to a substrate by vapor deposition using a metal mask. Thus, improvement of performance of the metal mask is important for improving the image quality of the organic EL display device.

For example, Japanese Patent Laid-Open No. 2015-163734 discloses a method for manufacturing a metal mask in which through-holes can be formed accurately.

A metal mask has an effective region in which through-holes are disposed, and a peripheral region positioned around the effective region, for example. Such a metal mask is installed on a frame and used for vapor deposition of pixels.

It has been found that when forming the effective region by etching, etching may progress excessively in a boundary portion between the effective region and the peripheral region. Such excessive progress of etching reduces the thickness of the boundary portion between the effective region and the peripheral region. Then, the boundary portion is deformed or broken.

The present disclosure has been made in view of the above-described problems, and has an object to provide a metal mask in which deformation and breakage are less likely to occur, and a method for manufacturing the metal mask.

### SUMMARY OF THE INVENTION

A metal mask according to one embodiment of the present disclosure includes an effective region, a peripheral region, and a dummy region. The effective region includes a first through-hole and a first top part. The first top part has a height H1. The peripheral region is positioned around the effective region. The dummy region is positioned between the effective region and the peripheral region. The dummy region includes a second top part. The second top part has a height H2. The height H2 is greater than the height H1.

A method for manufacturing the above-described metal mask according to one embodiment of the present disclosure includes a step of preparing a metal plate including a first surface and a second surface positioned opposite to the first surface, and an etching step of etching the metal plate to form the metal mask. The metal mask includes an effective region, a peripheral region, and a dummy region. The effective region includes a first through-hole and a first top part. The first top part has a height H1. The peripheral region is positioned around the effective region. The dummy region is positioned between the effective region and the peripheral region. The dummy region includes a second top part. The second top part has a height H2. The height H2 is greater than the height H1.

### Advantageous Effects of Invention

At least one embodiment of the present disclosure provides a metal mask in which deformation and breakage are less likely to occur in the boundary portion, and a method for manufacturing the metal mask.

### BRIEF DESCRIPTION OF THE DRAWINGS

FIG. 1 is a diagram showing a metal mask device including a metal mask according to one embodiment of the present disclosure;

FIG. 2 is a cross-sectional view showing a vapor deposition device according to the one embodiment of the present disclosure;

FIG. 3 is a plan view showing the metal mask according to the one embodiment of the present disclosure;

FIG. 4A is a perspective view of an effective region of the metal mask according to the one embodiment of the present disclosure as seen from a second surface side;

FIG. 4B is a perspective view of a dummy region of the metal mask according to the one embodiment of the present disclosure as seen from the second surface side;

FIG. 5A is a plan view showing an aspect of the dummy region of the metal mask according to the one embodiment of the present disclosure;

FIG. 5B is a plan view showing an aspect of the dummy region of the metal mask according to the one embodiment of the present disclosure;

FIG. 6 is a plan view of the effective region and the dummy region of the metal mask according to the one embodiment of the present disclosure as seen from the second surface side;

FIG. 7 is a cross-sectional view taken along the line IV-IV in FIG. 6;

FIG. 8 is a cross-sectional view taken along the line V-V in FIG. 6;

FIG. 9 is a cross-sectional view taken along the line VI-VI in FIG. 6;

FIG. 10 is a schematic view for describing an example of a method for manufacturing a metal mask;

FIG. 11 is a diagram showing an example of a step of forming a resist film on a metal plate;

FIG. 12 is a diagram showing an example of a step of patterning the resist film;

FIG. 13 is a diagram showing an example of a first surface etching step;

FIG. 14 is a diagram showing an example of a second surface etching step;

FIG. 15 is a diagram showing an example of a second surface etching step;

FIG. 16 is a diagram showing an example of the second surface etching step;

FIG. 17 is a perspective view of a dummy region having a blind recess; and

FIG. 18 is a plan view showing an example of a pattern of vapor deposition layers of an organic EL display device.

### DETAILED DESCRIPTION OF THE PREFERRED EMBODIMENT

Hereinafter, an embodiment of the present disclosure will be described with reference to the drawings. Note that in the drawings attached to the present specification, for convenience of ease of illustration and understanding, scale ratios, longitudinal and lateral dimensional ratios, and the like are exaggerated by changing from the actual ones in some cases.

In the present specification and the present drawings, description will be given citing an example of a metal mask to be used for patterning an organic material on a substrate in a desired pattern when manufacturing an organic EL display device, and a method for manufacturing the metal mask in one embodiment of the present specification unless particularly described. However, the present disclosure is not limited to such an application, but can be applied to metal masks to be used for various applications. For example, the metal mask of the present disclosure may be used for manufacturing a device for displaying or projecting an image or video for expressing virtual reality called VR or augmented reality called AR.

In the present specification and/or the present drawings, interpretation will be made as indicated below unless particularly described.

Terms that mean a substance on which a certain component is based may not be distinguished from each other only based on different names. For example, terms such as a “substrate”, a “base material”, a “plate”, a “sheet”, and a “film” are relevant to the above description.

Terms and/or numerals that mean shapes and/or geometric conditions are not necessarily limited to their strict definitions, but may be construed to include a range to a degree that similar functions may be expected. For example, terms such as “parallel” and/or “orthogonal” are relevant to the above-described terms. Values such as “values of length” and/or “values of angle” are relevant to the above-described numerals.

In some cases where a component is expressed as being “on”, “under”, “on an upper side of”, “on a lower side of”, “above”, or “below” another component, the cases may include an aspect in which the component is in direct contact with the other component, and an aspect in which a different component is included between the component and the other component. In other words, the aspect in which a different component is included between the component and the other component may be expressed as the component and the other component being indirectly connected to each other. The expression “on”, “upper side”, or “above” can be exchanged to the expression “under”, “lower side”, or “below”. In other words, an up-down direction may be reversed.

Identical portions and/or portions that have a similar function are designated by identical reference characters or like reference characters, and repeated description is omitted in some cases. The ratio of dimensions in the drawings differs from an actual ratio in some cases. Illustration of some components of an embodiment is omitted in the drawings in some cases.

One or more embodiments and one or more modifications may be combined within a range where no contradiction occurs. One or more embodiments may be combined within a range where no contradiction occurs. One or more modifications may be combined within a range where no contradiction occurs.

In a case where a plurality of steps are disclosed in relation to a method such as a manufacturing method, another undisclosed step may be performed between the disclosed steps. The order of the steps is not limited within a range where no contradiction occurs.

A numeral range expressed by the word “to” includes numerals placed in front of and behind the word “to”. For example, a numeral range expressed as “34 to 38 mass %” is identical to a numeral range expressed as “34 mass % or more and 38 mass % or less”.

A numeral range of a numeral described in the present disclosure may be defined by combining any one of a plurality of upper-limit candidate values and any one of a plurality of lower-limit candidate values. Besides, any two of the plurality of upper-limit candidate values may be combined to define the numeral range, or any two of the plurality of lower-limit candidate values may be combined to define the numeral range without particular mention.

One embodiment of the present disclosure will be described in the following paragraphs. One embodiment of the present disclosure is an example of embodiments of the present disclosure. The present disclosure is not construed as being limited only to the one embodiment of the present disclosure.

A first aspect of the present disclosure is a metal mask including an effective region, a peripheral region, and a dummy region, wherein
the effective region includes a first through-hole and a first top part,
the first top part has a height H1,
the peripheral region is positioned around the effective region,
the dummy region is positioned between the effective region and the peripheral region,
the dummy region includes a second top part,
the second top part has a height H2, and
the height H2 is greater than the height H1.

In a second aspect of the present disclosure, in the metal mask according to the first aspect described above,
the dummy region may be a region equal to a range having two or more rows and five or less rows of the second top parts.

In a third aspect of the present disclosure, in the metal mask according to the first aspect or the second aspect described above,
the height H2 close to the peripheral region may be greater than the height H2 close to the effective region on an identical straight line intersecting the dummy region from the effective region to the peripheral region.

In a fourth aspect of the present disclosure, in the metal mask according to any of the first to third aspects described above,
the height H2 may be 1.05 times the height H1 or more and 4.00 times the height H1 or less.

In a fifth aspect of the present disclosure, in the metal mask according to any of the first to fourth aspects described above, the metal mask may include a first surface and a second surface positioned opposite to the first surface,
the dummy region may include a second through-hole,
the first through-hole may have a first recess on the first surface side, and a second recess, a first connection part, and a first angle θ1 on the second surface side,
the first connection part may be a ridge part where the first recess and the second recess are connected to each other,
the first angle θ1 may be an angle made by a straight line K1 with respect to a thickness direction N of the metal mask, the straight line K1 passing through a portion Pia of the first connection part closest to the first top part and a portion P2a of the first top part closest to the first connection part, the second through-hole may have a third recess on the first surface side, and a fourth recess, a second connection part, and a second angle θ2 on the second surface side,
the second connection part may be a ridge part where the third recess and the fourth recess are connected to each other,
the second angle θ2 may be an angle made by a straight line K2 with respect to the thickness direction N of the metal mask, the straight line K2 passing through a portion P1b of the second connection part closest to the second top part and a portion P2b of the second top part closest to the second connection part, and
the second angle θ2 may be smaller than the first angle θ1.

In a sixth aspect of the present disclosure, in the metal mask according to any of the first to fifth aspects described above,
the metal mask may include a first surface and a second surface positioned opposite to the first surface,
the dummy region may include a second through-hole,
the first through-hole may have a first recess on the first surface side, and a second recess, a first connection part, and a height H3 on the second surface side,
the first connection part may be a ridge part where the first recess and the second recess are connected to each other,
the height H3 may be a height from the first surface to the first connection part,
the second through-hole may have a third recess on the first surface side, and a fourth recess, a second connection part, and a height H5 on the second surface side,
the second connection part may be a ridge part where the third recess and the fourth recess are connected to each other,
the height H5 may be a height from the first surface to the second connection part, and
the height H5 may be greater than the height H3.

In a seventh aspect of the present disclosure, in the metal mask according to any of the first to sixth aspects described above,
the first through-hole may have the height H3 and a height H4,
the height H3 may be a height from the first surface to the first connection part,
the height H4 may be a height from the second surface to the first connection part, and
the height H3 may be smaller than the height H4.

In an eighth aspect of the present disclosure, in the metal mask according to any of the first to seventh aspects described above,
the dummy region may include a top part remaining unetched.

A ninth aspect of the present disclosure is a method for manufacturing a metal mask, including:
a step of preparing a metal plate including a first surface and a second surface positioned opposite to the first surface; and
an etching step of etching the metal plate to form the metal mask, wherein
the metal mask includes an effective region, a peripheral region, and a dummy region,
the effective region includes a first through-hole and a first top part,
the first top part has a height H1,
the peripheral region is positioned around the effective region,
the dummy region is positioned between the effective region and the peripheral region,
the dummy region includes a second top part,
the second top part has a height H2, and
the height H2 is greater than the height H1.

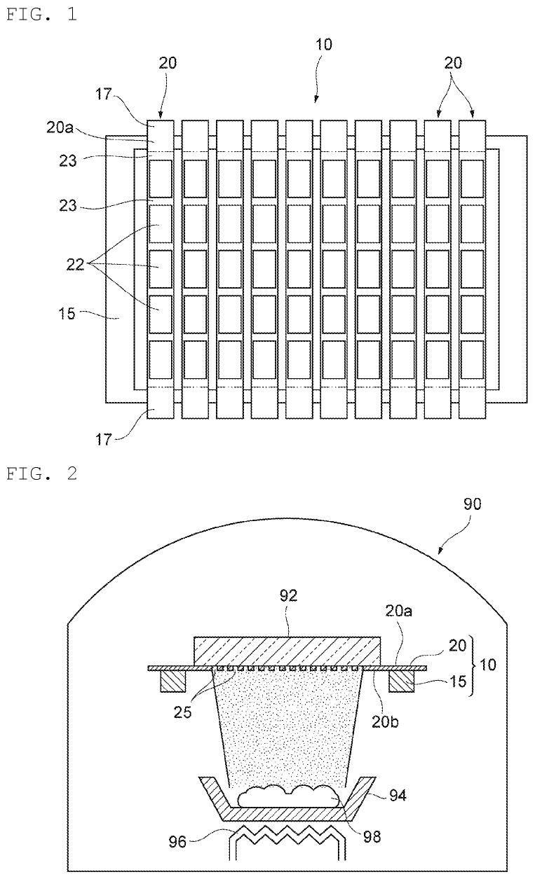

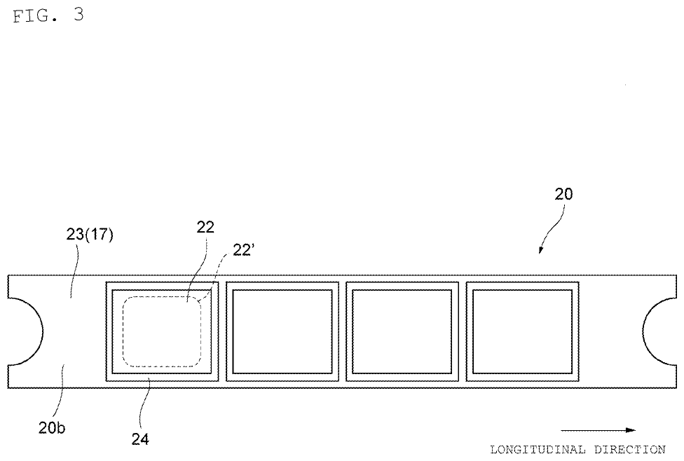

First, an example of a vapor deposition device including a metal mask will be described with reference to FIG. 1 and FIG. 2. Herein, FIG. 1 is a plan view of a metal mask device 10 including metal masks 20 according to one embodiment of the present disclosure, as seen from a first surface 20a side of the metal masks 20, and FIG. 2 is a cross-sectional view showing the vapor deposition device.

As shown in FIG. 1, each of the metal masks 20 may have a substantially rectangular shape extending in one direction. The metal mask device 10 may include the plurality of metal masks 20 made of substantially rectangular metal plates, and a frame 15 attached to the peripheries of the plurality of metal masks 20. The plurality of metal masks 20 may be aligned in a width direction orthogonal to a length direction of the metal masks 20. Each of the metal masks 20 may be fixed to the frame 15 by welding, for example, at both ends in the length direction of the metal mask 20.

The metal mask device 10 may include a member fixed to the frame 15 and partially overlapping the metal masks 20 in a thickness direction of the metal masks 20. Examples of such a member include, but not particularly limited to, a member extending in a direction crossing the length direction of the metal masks 20 and supporting the metal masks 20, a member overlapping a gap between adjacent two metal masks, and the like.

This metal mask device 10 is supported in a vapor deposition device 90 so as to face a substrate 92 as shown in FIG. 2. Herein, the substrate 92 is an evaporation target such as a glass substrate. In a case where the metal mask device 10 is stored in the vapor deposition device 90 as shown in FIG. 2, a surface of the metal mask 20 facing the substrate 92 is called the first surface 20a, and a surface of the metal mask 20 positioned on a crucible 94 side that holds a vapor deposition material 98 is called a second surface 20b.

In the vapor deposition device 90, the metal mask 20 is located on a surface of the substrate 92 on the crucible 94 side. Herein, the metal mask 20 and the substrate 92 may be brought into close contact with each other by a magnetic force.

In the vapor deposition device 90, the crucible 94 that stores the vapor deposition material 98, and a heater 96 that heats the crucible 94 may be disposed below the metal mask device 10. Herein, the vapor deposition material 98 may be an organic light emitting material as an example. The vapor deposition material 98 in the crucible 94 is vaporized or sublimated by the heat from the heater 96. The vaporized or sublimated vapor deposition material 98 adheres to the substrate 92 by way of a first through-holes 25a of the metal mask 20. The vapor deposition material 98 is thereby deposited on the surface of the substrate 92 in a desired pattern corresponding to the position of the first through-holes 25a of the metal mask 20.

In a case of intending to vapor-deposit different types of vapor deposition materials in accordance with pixels such as RGB, the vapor deposition material 98 may be deposited on the surface of the substrate 92 using different metal masks 20 in accordance with the colors of organic light emitting materials. For example, an organic light emitting material for red, an organic light emitting material for green, and an organic light emitting material for blue may be sequentially deposited on the substrate 92. Alternatively, the metal mask 20 (the metal mask device 10) and the substrate 92 may be relatively moved little by little in an arrangement direction (the aforementioned one direction) of the first through-holes 25a to sequentially deposit the organic light emitting material for red, the organic light emitting material for green, and the organic light emitting material for blue.

Note that the frame 15 of the metal mask device 10 may be attached to the peripheries of the rectangular metal masks 20. The frame 15 holds the metal masks 20 in a stretched state. The metal masks 20 and the frame 15 may be fixed to each other by spot welding, for example.

FIG. 1 shows an example in which the plurality of elongated metal masks 20 are installed on the frame 15. Alternatively, a large-sized single metal mask 20 having substantially the same shape as the shape of the frame 15 may be installed on the frame 15.

Hereinafter, the metal mask of the present disclosure will be described in detail using as an example a metal mask to be used for vapor deposition of an organic light emitting material for an organic EL display device. However, the application of the metal mask of the present disclosure is not limited to vapor deposition of an organic light emitting material for an organic EL display device, but in addition, the metal mask of the present disclosure can also be used for manufacturing a device for displaying or projecting an image or video for expressing virtual reality called VR or augmented reality called AR.

The metal mask of the present disclosure includes the effective region, the peripheral region, and the dummy region. The effective region includes the first through-hole and the first top part. The first top part has the first height H1. The peripheral region is positioned around the effective region. The dummy region is positioned between the effective region and the peripheral region. The dummy region includes the second top part. The second top part has the second height H2. The second height H2 is greater than the first height H1.

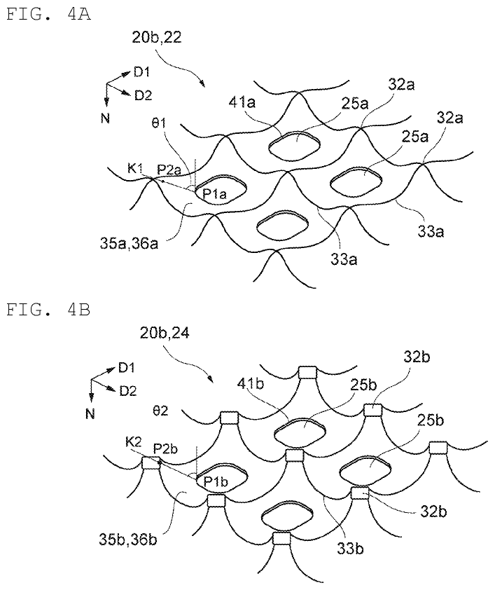

FIG. 3 shows a plan view of the metal mask 20 of one embodiment of the present disclosure. The metal mask 20 may be obtained by forming the first through-holes 25a in the metal plate 51 by etching. As shown in FIG. 3, the metal mask 20 includes effective regions 22 in which the first through-holes 25a are disposed, a peripheral region 23 positioned around the effective regions 22, and dummy regions 24 each positioned at least partially at a boundary between the effective region 22 and the peripheral region 23. The metal mask 20 may have a substantially rectangular contour in plan view.

A height T from the first surface to the second surface preferably may be 50 μm or less, may be 40 μm or less, may be 35 μm or less, may be 30 μm or less, may be 25 μm or less, may be 20 μm or less, may be 18 μm or less, may be 15 μm or less, or may be 13 μm or less. By reducing the height T, the vapor deposition material 98 can be prevented from adhering to the second wall surface 36a of the second recess 35a in a vapor deposition step. Note that such a phenomenon in which adhesion of the vapor deposition material to the substrate is inhibited by the wall surface of the through-hole is also referred to as shadow.

In addition, the height T preferably may be 2 μm or more, may be 5 μm or more, may be 10 μm or more, or may be 15 μm or more. Increasing the height T leads to a tendency that the strength of the metal mask 20 is improved more. This can prevent the effective regions 22 from being deformed or broken, for example.

Note that the range of the height T may be determined by a combination of any one of the above-described plurality of lower-limit candidate values and any one of the above-described plurality of upper-limit candidate values. The height T is a thickness of a portion of the metal mask 20 in which the first recess 30a and the second recess 35a are not formed. In other words, the height T may be a thickness equal to the thickness of the peripheral region 23 or the thickness of the metal plate 51 of the metal mask 20.

It is preferable that the thermal expansion coefficient of the metal mask 20 should be equivalent in value to the thermal expansion coefficient of the frame 15 or the thermal expansion coefficient of the substrate 92. This can prevent occurrence of misalignment resulting from differences in dimensional change among the metal mask 20, the frame 15, and the substrate 92 during vapor deposition treatment performed under a high temperature atmosphere. Degradation in dimensional accuracy and positional accuracy of the vapor deposition material 98 adhering to the substrate 92, resulting from the misalignment, can thus be prevented.

For example, in a case where a glass substrate is used as the substrate 92, an iron alloy containing nickel may be used as a main material of the metal mask 20 and the frame 15. Examples of an iron alloy containing nickel can include an iron alloy containing 30 mass % or more and 54 mass % or less nickel. More specifically, such an iron alloy can include an invar material containing 34 mass % or more and 38 mass % or less nickel, a super-invar material further containing cobalt in addition to 30 mass % or more and 34 mass % or less nickel, a low thermal expansion Fe—Ni plating alloy containing 48 mass % or more and 54 mass % or less nickel, and the like.

Note that in a case where the temperatures of the metal mask 20, the frame 15, and the substrate 92 do not reach a high temperature in the vapor deposition treatment, it is not particularly necessary to make the thermal expansion coefficients of the metal mask 20 and the frame 15 equivalent in value to the thermal expansion coefficient of the substrate 92. In this case, an iron alloy containing chromium, such as stainless steel, nickel, a nickel-cobalt alloy, or the like can be used as the material of the metal plate 51 to be described later that constitutes the metal mask 20, besides the above-described iron alloy containing nickel.

The metal mask 20 may have the plurality of effective regions 22. For example, the metal mask 20 may have the plurality of effective regions 22 disposed in line at predetermined intervals in one direction parallel to the longitudinal direction of the metal mask 20, as shown in FIG. 3. Such a metal mask 20 is referred to as what is called a stick-like metal mask in some cases. In this case, the metal mask device 10 may have the plurality of metal masks 20 disposed in the width direction orthogonal to the longitudinal direction of the metal mask 20 and attached to the frame 15 as shown in FIG. 1.

As another example, the metal mask 20 may have a plurality of effective regions 22 disposed at predetermined intervals in one direction parallel to one side of the metal mask 20, and may have a plurality of effective regions 22 disposed at predetermined intervals in another direction orthogonal to the one direction. In other words, the metal mask 20 may have the effective regions 22 in a plurality of rows. In this case, the metal mask device 10 may have a single metal mask 20, having a size close to the size of the frame 15, attached to the frame 15.

The effective region 22 includes the first through-hole 25a and a first top part 32a. The effective region 22 may include a plurality of the first through-holes 25a and a plurality of the first top parts 32a. Herein, the first top part 32a refers to a portion where the height has the local maximum value on a plane. The first top part 32a may be formed on the second surface 20b side. The effective region 22 may be a region that faces a section on the substrate 92 where organic light emitting materials will vapor-deposit to form pixels, and functions as a mask during vapor deposition.

A single effective region 22 may be configured to correspond to a display region of a single organic EL display device 100. The use of such a metal mask device 10 enables multifaceted vapor deposition of the organic EL display device. Alternatively, a single effective region 22 may be configured to correspond to a display region of a plurality of organic EL display devices.

The effective region 22 may have a substantially rectangular contour in plan view. Alternatively, the effective region 22 may have contours of various shapes such as a circular shape depending on the shape of the display region of the substrate 92.

FIG. 4A shows a perspective view of the effective region 22 as seen from the second surface 20b side as one embodiment of the present disclosure. The effective region 22 may have the first through-holes 25a formed by etching. As shown in FIG. 4A, the plurality of first through-holes 25a formed in each of the effective regions 22 are disposed in a predetermined pattern. For example, when seen from the second surface 20b side, the first through-holes 25a may be disposed respectively at predetermined pitches in the first direction D1 and the second direction D2 crossing each other. The first through-holes 25a may be surrounded by a plurality of ridge lines 33a including the plurality of first top parts 32a. Adjacent ones of the second recesses 35a may be connected to each other with the ridge line 33a.

As shown in FIG. 4A, the ridge line 33a refers to a boundary formed by joining of second wall surfaces 36a of adjacent ones of the second recesses 35a. The height of this ridge line 33a is not constant, but may vary in a rippling manner. Note that the height of the ridge line 33a can also be regarded as the position of the ridge line 33a in the thickness direction of the metal mask 20. As a general tendency, the height of the ridge line 33a changes in accordance with the distance from the center of the first through-hole 25a, and rises as the distance increases.

The first top part 32a refers to a portion of the ridge line 33a where the height has the local maximum value. In the case of FIG. 4A, the first top part 32a is surrounded by four of the first through-holes 25a. The first top part 32a is positioned on the ridge line at a position relatively far from the center of the first through-hole 25a.

As the height H1 of the first top part 32a is smaller, a first angle θ1 which will be described later is likely to be large. When the first angle θ1 is large, the utilization efficiency and vapor deposition accuracy of the vapor deposition material 98 are likely to be improved more. From such perspectives, it is preferable that the height H1 of the effective region 22 should be relatively small.

The peripheral region 23 is the region positioned around the effective regions 22, and may be positioned to surround the effective regions 22. The peripheral region 23 is the region positioned around the effective regions 22 to support the effective regions 22. The peripheral region 23 does not include the first through-holes 25a for passage of the vapor deposition material. However, a through-hole not intended for passage of the vapor deposition material and a recess formed by half-etching or the like may be formed in the peripheral region 23 for various purposes.

The peripheral region may have an end 17 of the metal mask to be fixed to the frame. In the case of the metal mask 20 shaped as an elongated stick as shown in FIG. 1, the ends 17 may be positioned at both ends in the length direction. The end 17 may have a U-shaped notch or the like. On the other hand, in the case where the metal mask is a large-sized mask having substantially the same shape as the frame, the end 17 may be positioned on the periphery of the metal mask. The end 17 may be partially cut after the metal mask is fixed to the frame.

In one embodiment of the present disclosure, the end 17 may be formed integrally with the other peripheral region 23 as shown in FIG. 3, or may be formed by a member separate from the other peripheral region. In this case, the end 17 may be bonded to another portion of the peripheral region by welding, for example.

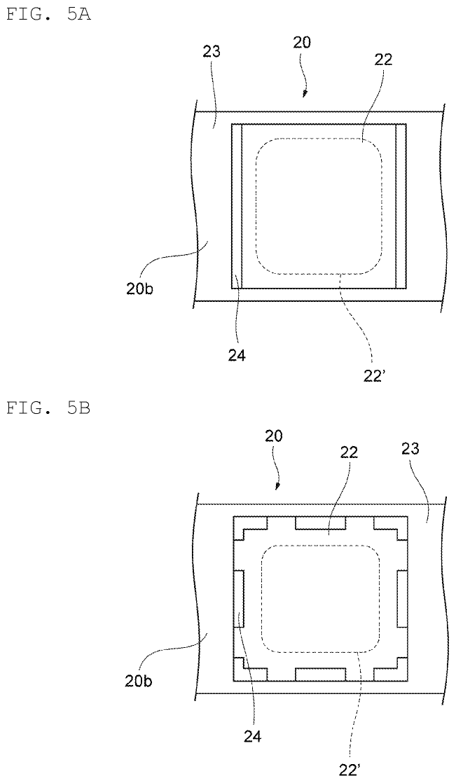

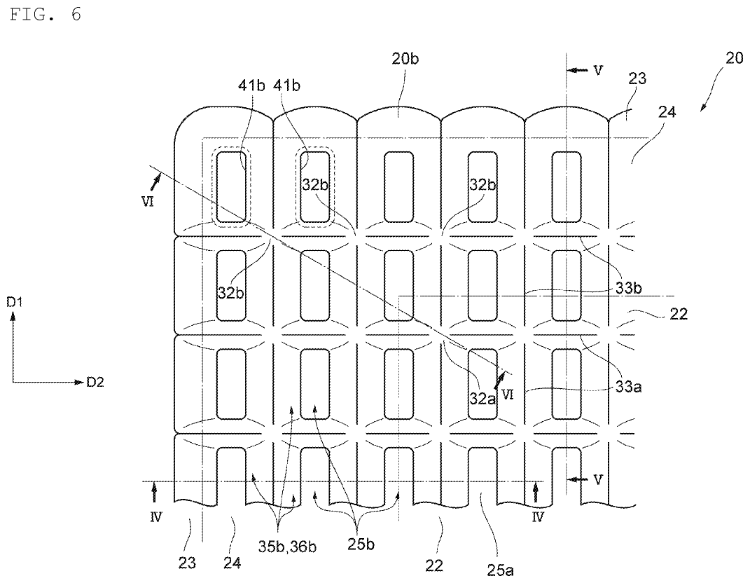

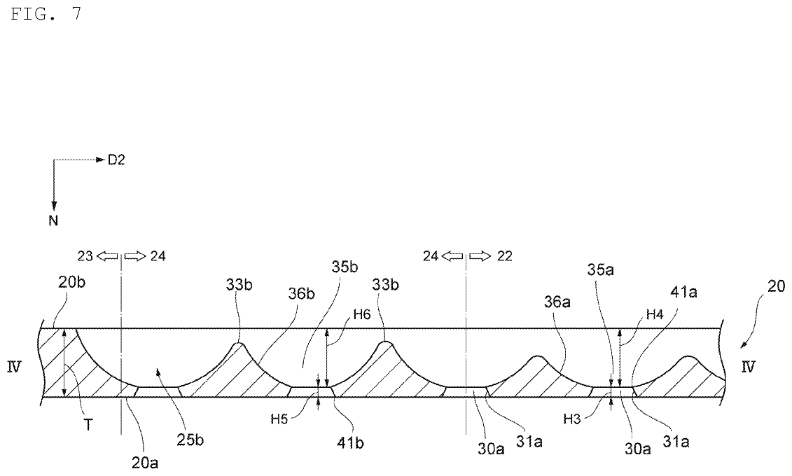

The dummy region 24 is a region positioned between the effective region 22 and the peripheral region 23. The dummy region 24 may be positioned all around between the effective region 22 and the peripheral region 23 as shown in FIG. 3. Alternatively, the dummy region 24 may be positioned on at least one side between the effective region 22 and the peripheral region 23 having substantially rectangular shapes as shown in FIG. 5A or FIG. 5B. For example, the dummy regions 24 may be positioned on opposite two sides of the boundary between the effective region 22 and the peripheral region 23 having substantially rectangular shapes as shown in FIG. 5A. Alternatively, one or more dummy regions 24 may be formed on one side of the boundary between the effective region 22 and the peripheral region 23 having substantially rectangular shapes as shown in FIG. 5B.

In the case where the metal mask 20 is shaped as a stick as shown in FIG. 3, the dummy regions 24 may be positioned on sides parallel to the length direction on the boundary between the effective region 22 and the peripheral region 23, or may be positioned on sides parallel to the direction orthogonal to the length direction as shown in FIG. 5A. When the dummy regions 24 are positioned on the sides parallel to the direction orthogonal to the length direction, deformation and breakage are likely to be prevented when the metal mask 20 is installed on the frame 15.

The dummy region 24 includes a second top part 32b. Herein, the second top part 32b refers to a portion where the height has the local maximum value on a plane. This local maximum value may include a portion remaining unetched. The second top part 32b may be formed on the second surface 20b side. Note that the dummy region 24 may include second through-holes 25b.

In one embodiment of the present disclosure, the height H2 of the second top part 32b is greater than the height H1. This secures the strength of the metal mask 20 and prevents deformation and breakage in the region between the effective region 22 and the peripheral region 23.

In the case of forming the effective region 22 on the metal plate 51 by etching, etching tends to be likely to progress excessively between the effective region 22 and the peripheral region 23. A place between the effective region 22 and the peripheral region 23 can also be regarded as the border between a region with holes and a region without holes in a resist pattern. When etching progresses excessively, the metal mask 20 becomes partially thin in the region between the effective region 22 and the peripheral region 23, so that the connection strength may be degraded. Then, the metal mask 20 is likely to be deformed, and the effective region 22 is likely to be broken starting from the peripheral region 23.

Thus, one embodiment of the present disclosure is configured such that the height H2 of the second top part 32b that the dummy region 24 has is greater than the height H1 of the first top part 32a in the effective region 22. This secures the strength of the metal mask 20 and prevents deformation and breakage in the region between the effective region 22 and the peripheral region 23.

The range of the dummy region 24 positioned between the effective region 22 and the peripheral region 23 may be indicated by the number of rows of the second top parts 32b. For example, the dummy region 24 may be a region equal to a range having one or more rows of the second top parts 32b counting from the peripheral region 23 side, may be a region equal to a range having two or more rows of the second top parts 32b, or may be a region equal to a range having three or more rows of the second top parts 32b. In addition, the dummy region 24 may be a region equal to a range having 100 or less rows of the second top parts 32b counting from the peripheral region 23 side, may be a region equal to a range having 50 or less rows of the second top parts 32b, may be a region equal to a range having 10 or less rows of the second top parts 32b, or may be a region equal to a range having 5 or less rows of the second top parts 32b. The range of the dummy region may be determined by a combination of any one of the above-described plurality of lower-limit candidate values and any one of the above-described plurality of upper-limit candidate values for the above-described number of rows of the second top parts 32b. The rows of the second top parts 32b in the plurality of rows may extend substantially parallel to the boundary between the effective region 22 and the peripheral region 23.

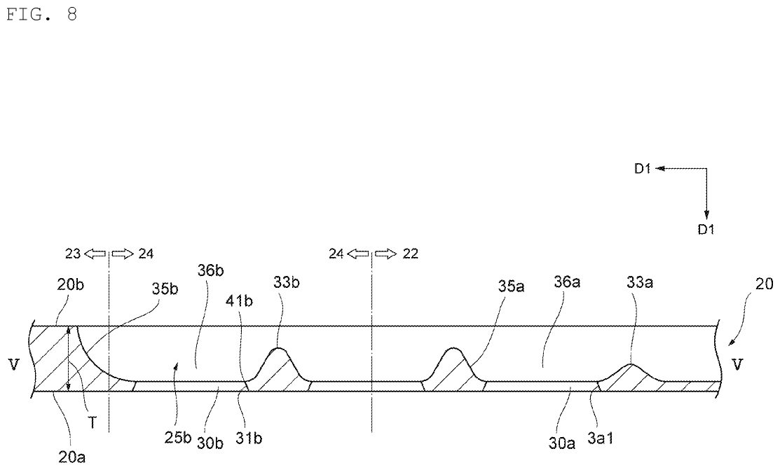

For example, FIG. 6 shows an aspect in which two rows of the second top parts 32b are aligned in the direction D1, and one row of the second top parts 32b is aligned in the direction D2. The range of the dummy region 24 may be a region such as the region equal to the range having one or more rows of the second top parts 32b, as described above. Herein, the “equal region” refers to a region having a range equivalent to the range in which one row of the second top parts 32b is aligned in the direction D2 in FIG. 6, for example.

The dummy region 24 may include the second through-holes 25b. Note that the dummy region 24 is different from the effective region 22 in that even if the vapor deposition material passes through the second through-holes 25b present in the dummy region 24 and adheres to the substrate 92, the vapor deposition material may not be used as a light-emitting element of a display device.

FIG. 4B shows a perspective view of the dummy region 24 as seen from the second surface 20b side, as one embodiment of the present disclosure. As shown in FIG. 4B, a plurality of the second through-holes 25b may be arranged in the dummy region 24 in a pattern resembling the effective region 22. Also in the dummy region 24, the second through-hole 25b may be surrounded by the plurality of second top parts 32b and a plurality of ridge lines 33b. Adjacent ones of the second top parts 32b may be connected to each other by the ridge line 33b.

The second top part 32b refers to a portion where the height has the local maximum value, or a portion remaining unetched, in plan view, as shown in FIG. 4B. In the case of FIG. 4B, the second top part 32b is surrounded by four of the second through-holes 25b, and the second top part 32b is positioned at a position relatively far from the center of each of the second through-holes 25b.

As shown in FIG. 4B, the ridge line 33b refers to a boundary formed by joining of fourth wall surfaces 36b of adjacent ones of the fourth recesses 35b. The height of this ridge line 33 is not constant, but may vary in a rippling manner. Note that the height of the ridge line 33 can also be regarded as the position of the ridge line 33 in the thickness direction of the metal mask. As a general tendency, the height of the ridge line 33 changes in accordance with the distance from the center of the second through-hole 25b, and rises as the distance increases.

As the height H2 of the second top part 32b is greater, the connection strength between the effective region 22 and the peripheral region 23 is improved more, which can prevent deformation and breakage.

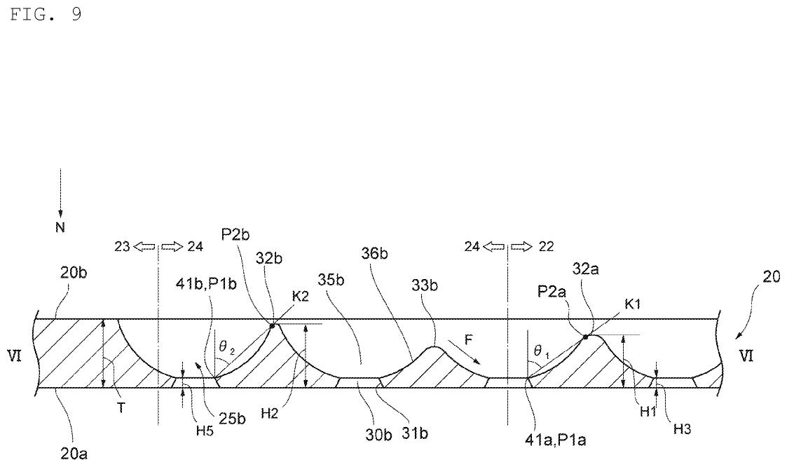

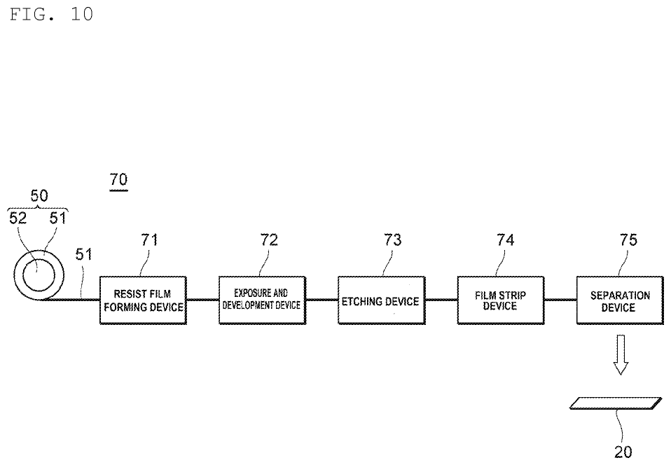

An example of the second through-holes 25b that the effective region 22 and the dummy region 24 have will be described in further detail mainly with reference to FIG. 6 to FIG. 9. FIG. 6 is a partial plan view of the effective region 22, the peripheral region 23, and the dummy region 24 of the metal mask 20 as seen from the second surface 20b side. FIG. 7 is a cross-sectional view taken along the line IV-IV in FIG. 6. FIG. 8 is a cross-sectional view taken along the line V-V in FIG. 6. FIG. 9 is a cross-sectional view taken along the line VI-VI in FIG. 6.

Specifically, FIG. 7 to FIG. 8 are cross-sectional views obtained in a case where the effective region 22, the peripheral region 23, and the dummy region 24 of the metal mask 20 are cut in a direction passing through the ridge line 33a between the first through-holes 25a and the ridge line 33b between the second through-holes 25b. FIG. 9 is a cross-sectional view obtained in a case where the effective region 22, the peripheral region 23, and the dummy region 24 of the metal mask 20 are cut in a direction passing through the first top part 32a between the first through-holes 25a and the second top part 32b between the second through-holes 25b.

As shown in FIG. 6, at least some of the first through-holes 25a and the second through-holes 25b are disposed respectively at predetermined pitches in the first direction D1 and the second direction D2 crossing each other. The first direction D1 and the second direction D2 may each coincide with the length direction or the width direction of the metal mask 20, or may be inclined with respect to the length direction or the width direction of the metal mask 20. For example, the first direction D1 may be inclined at 45 degrees with respect to the length direction of the metal mask 20.

The pitches of the first through-holes 25a in the effective region 22 and the second through-holes 25b in the dummy region 24 are not particularly limited. For example, in a case where the metal mask 20 is used for fabricating a display (approximately 2 inch or more and 5 inch or less) of a mobile phone, a digital camera, or the like, the pitches of the first through-holes 25a and the second through-holes 25b may be set at approximately 28 μm or more and 254 μm or less in each of the first direction D1 and the second direction D2.

The first through-hole 25a extends through the metal mask 20 in the thickness direction. As shown in FIG. 6 to FIG. 9, the first through-hole 25a may be formed by communication of the first recess 30a formed on the first surface 20a side and the second recess 35a formed on the second surface 20b side. Etching of the metal plate 51 may progress isotropically in various directions from holes in a resist pattern. Thus, the first recess 30a and the second recess 35a have shapes such that their cross sectional areas at respective positions in the thickness direction of the metal mask 20 gradually decrease with progress in the thickness direction from the surface.

The first through-hole 25a may have a first connection part 41a, the first angle θ1, and a height H3. Herein, the first connection part 41a is a ridge part where the first recess 30a and the second recess 35a are connected to each other. At the first connection part 41a, the direction in which the wall surface of the first through-hole 25a spreads changes discontinuously. In one embodiment of the present disclosure, the opening area of the first through-hole 25a in plan view may be minimized at the first connection part 41a. Alternatively, the opening area of the first through-hole 25a may be minimized at a position in the thickness direction of the metal mask 20 other than the first connection part 41a.

The first angle θ1 is an angle made by a straight line K1 with respect to the thickness direction N of the metal mask. Herein, the straight line K1 is a straight line passing through a portion P1a of the first connection part 41a closest to the first top part 32a and a portion P2a of the first top part 32a closest to the first connection part 41a. Further, the height H3 is the height from the first surface 20a to the first connection part 41a.

Note that the first recess 30a and the second recess 35a may herein be distinguished from each other by their depths. For example, as shown in FIG. 7, the first through-hole 25a may have the first recess 30a having the height H3 and the second recess 35a having a height H4. Herein, the height H3 is the height from the first surface 20a to the first connection part 41a. The height H4 is the height from the second surface 20b to the first connection part 41a. At this time, it is preferable that the height H3 should be smaller than the height H4. The surface having the first recess 30a in such a depth relationship may be the first surface 20a, and the surface having the second recess 35a may be the second surface 20b.

The ratio (H4/H3) of the height H4 to the height H3 preferably may be 1.5 or more, may be 2.0 or more, may be 2.5 or more, or may be 3.0 or more.

Increasing the ratio (H4/H3) as described above leads to a tendency that the utilization efficiency and vapor deposition accuracy of the vapor deposition material are improved more. Reducing the ratio (H4/H3) leads to a tendency that the effective region 22 can be prevented from being deformed or broken. Note that the range of the ratio (H4/H3) may be determined by a combination of any one of the above-described plurality of lower-limit candidate values and any one of the above-described plurality of upper-limit candidate values.

The depth relationship between the first recess 30a and the second recess 35a may be replaced by opening dimensions of the first recess 30a and the second recess 35a. For example, the opening dimension of the first recess 30a may be smaller than the opening dimension of the second recess 35a.

Adjacent two of the first through-holes 25a may be spaced apart in the planar direction of the first surface 20a on the first surface 20a side of the effective region 22. In other words, the first surface 51a of the metal plate 51 may be left between adjacent two of the first recesses 30a. Such a first through-hole 25a may be formed by etching the metal plate 51 such that the first surface 51a of the metal plate 51 is left between adjacent two of the first recesses 30a as in a manufacturing method which will be described later. Note that the first surface 51a of the metal plate 51 corresponds to the first surface 20a of the metal mask 20.

The second recesses 35a of adjacent two of the first through-holes 25a may be connected to each other on the second surface 20b side of the effective region 22. In other words, the second surface 51b of the metal plate 51 constituting the metal mask 20 may not be left between adjacent two of the second recesses 35a. Such a first through-hole 25a may be formed by etching the metal plate 51 such that the second surface 51b of the metal plate 51 is not left between adjacent two of the second recesses 35a as in the manufacturing method which will be described later. Note that the second surface 51b of the metal plate 51 corresponds to the second surface 20b of the metal mask 20.

On the second surface 20b in the effective region 22, the second surface 51b of the metal plate 51 may not be left between adjacent two of the second recesses 35a. In addition, the first surface 51a of the metal plate 51 may not be left on the whole second surface 20b in the effective region 22. In other words, a top part having the same thickness as the thickness of the metal plate 51 may not be present on the first surface 20a in the effective region 22.

The second through-hole 25b extends through the metal mask 20 in the thickness direction. As shown in FIG. 6 to FIG. 9, the second through-hole 25b may be formed by communication of a third recess 30b formed on the first surface 20a side and a fourth recess 35b formed on the second surface 20b side. Etching of the metal plate 51 may progress isotropically in various directions from holes in the resist pattern. Thus, the third recess 30b and the fourth recess 35b have shapes such that their cross sectional areas at respective positions in the thickness direction of the metal mask 20 gradually decrease with progress in the thickness direction from the surface.

The second through-hole 25b may have a second connection part 41b and a second angle θ2. Herein, the second connection part 41b is a ridge part where the third recess 30b and the fourth recess 35b are connected to each other. At the second connection part 41b, the direction in which the wall surface of the second through-hole 25b spreads changes discontinuously. In one embodiment of the present disclosure, the opening area of the second through-hole 25b in plan view may be minimized at the second connection part 41b. Alternatively, the opening area of the second through-hole 25b may be minimized at a position in the thickness direction of the metal mask 20 other than the second connection part 41b.

The second angle θ2 is an angle made by a straight line K2 with respect to the thickness direction N of the metal mask. Herein, the straight line K2 is a straight line passing through a portion P1b of the second connection part 41b closest to the second top part 32b and a portion P2b of the second top part 32b closest to the second connection part 41b. Further, a height H5 is the height from the first surface 20a to the second connection part 41b.

Note that the third recess 30b and the fourth recess 35b may herein be distinguished from each other by their depths. For example, as shown in FIG. 7, the second through-hole 25b has the third recess 30b having the height H5 and the fourth recess 35b having a height H6. Herein, the height H5 is the height from the first surface 20a to the second connection part 41b. The height H6 is the height from the second surface 20b to the second connection part 41b. At this time, it is preferable that the height H5 should be smaller than the height H6. The surface having the third recess 30b in such a depth relationship may be the first surface 20a, and the surface having the fourth recess 35b may be the second surface 20b.

The ratio (H6/H5) of the height H6 to the height H5 preferably may be 1.5 or more, 2.0 or more, may be 2.5 or more, or may be 3.0 or more.

Reducing the ratio (H6/H5) as described above leads to the tendency that the effective region 22 can be prevented from being deformed or broken. Note that the range of the ratio (H6/H5) may be determined by a combination of any one of the above-described plurality of lower-limit candidate values and any one of the above-described plurality of upper-limit candidate values.

The depth relationship between the third recess 30b and the fourth recess 35b may be replaced by opening dimensions of the third recess 30b and the fourth recess 35b. For example, the opening dimension of the third recess 30b may be smaller than the opening dimension of the fourth recess 35b.

Adjacent two of the second through-holes 25b on the first surface 20a side of the dummy region 24 may be spaced apart in the planar direction of the first surface 20a. In other words, the first surface 51a of the metal plate 51 may be left between adjacent two of the third recesses 30b. Such a second through-hole 25b may be formed by etching the metal plate 51 such that the first surface 51a of the metal plate 51 is left between adjacent two of the third recesses 30b as in the manufacturing method which will be described later. Note that the first surface 51a of the metal plate 51 corresponds to the first surface 20a of the metal mask 20.

The fourth recesses 35b of adjacent two of the second through-holes 25b may be connected to each other on the second surface 20b side in the dummy region 24. In other words, the second surface 51b of the metal plate 51 constituting the metal mask 20 may not be left between adjacent two of the fourth recesses 35. Such a second through-hole 25b may be formed by etching the metal plate 51 such that the second surface 51b of the metal plate 51 is not left between adjacent two of the fourth recesses 35b as in the manufacturing method which will be described later. Note that the second surface 51b of the metal plate 51 corresponds to the second surface 20b of the metal mask 20.

The second surface 51b of the metal plate 51 may be left between adjacent two of the fourth recesses 35b on the second surface 20b in the dummy region 24, and the second surface 51b of the metal plate 51 may be left on the whole second surface 20b in the effective region 22. In other words, a top part having the same thickness as the thickness of the metal plate 51 may be present on the second surface 20b in the effective region 22.

In the vapor deposition step through use of the metal mask 20, the vapor deposition material 98 passes through the second recess 35a, the opening area of which gradually decreases, and adheres to the substrate 92. A part of the vapor deposition material 98 moves in the thickness direction N of the substrate 92 from the crucible 94 toward the substrate 92. On this occasion, a part of the vapor deposition material 98 may move in a direction inclined with respect to the thickness direction N of the substrate 92 as indicated by an arrow F in FIG. 9. The part of the vapor deposition material 98 moving in the inclined direction may reach and adhere to the second wall surface 36a before passing through the first through-hole 25a and reaching the substrate 92. As the proportion of the vapor deposition material 98 that adheres to the second wall surface 36a is higher, the utilization efficiency of the vapor deposition material 98 in the vapor deposition step degrades.

From the perspective of the utilization efficiency of the vapor deposition material 98, a configuration in which the second wall surfaces 36a of adjacent two of the second recesses 35a join together on the second surface 20b side as shown in FIG. 7 and the like is preferable. The second wall surface 36a constituting a large part of the first through-hole 25a is thereby inclined effectively with respect to the thickness direction of the metal mask. This enables vapor deposition in a desired pattern to be performed stably and accurately while effectively improving the utilization efficiency of the vapor deposition material 98.

From such perspectives, it is preferable to configure the height H1 of the first top part 32a in the effective region 22 as will be described below. Herein, the first top part 32a refers to a portion where the height has the local maximum value on the second surface 20b side in the effective region 22.

It is preferable that the first top part 32a should be positioned in a central region 22′ of the effective region 22 as shown in FIG. 3 and FIGS. 5A and 5B. Herein, the central region 22′ refers to a central portion of the effective region 22. The central region 22′ can also be regarded as a region spaced from the peripheral region 23 by a predetermined distance in the effective region 22. Such a central region 22′ is not particularly limited, and, for example, may be a range on the inner side from the peripheral region 23 toward the center of the effective region 22 by 150 rows or more of the number of the first through-holes 25a, may be a range on the inner side by 200 rows or more, may be a range on the inner side by 300 rows or more, or may be a range on the inner side by 500 rows or more. The upper limit of the number of the through-holes is not particularly restricted, and should only be a distance away from the peripheral region 23 toward the center of the effective region 22 by a predetermined rows or more.

The height H1 preferably may be 0.15 times the height T or more, may be 0.20 times or more, may be 0.25 times or more, may be 0.30 times or more, may be 0.35 times or more, may be 0.40 times or more, or may be 0.45 times or more.

The height H1 preferably may be 6 μm or more, may be 7 μm or more, may be 8 μm or more, may be 9 μm or more, or may be 10 μm or more. In addition, the height H1 preferably may be 16 μm or less, may be 15 μm or less, may be 14 μm or less, may be 13 μm or less, or may be 12 μm or less.

Setting the height H1 at the above-described lower limit value or more can prevent the effective regions 22 from being deformed or broken. Setting the height H1 at the above-described upper limit value or less leads to the tendency that the utilization efficiency of the vapor deposition material 98 is improved more and the vapor deposition accuracy is improved more. Note that the range of the height H1 may be determined by a combination of any one of the above-described plurality of lower-limit candidate values and any one of the above-described plurality of upper-limit candidate values.

The height H2 of the second top part 32b that the dummy region 24 has is greater than the height H1 of the first top part 32a in the effective region 22. This improves the strength in the dummy region 24 more, and can prevent the effective region 22 from being deformed or broken.

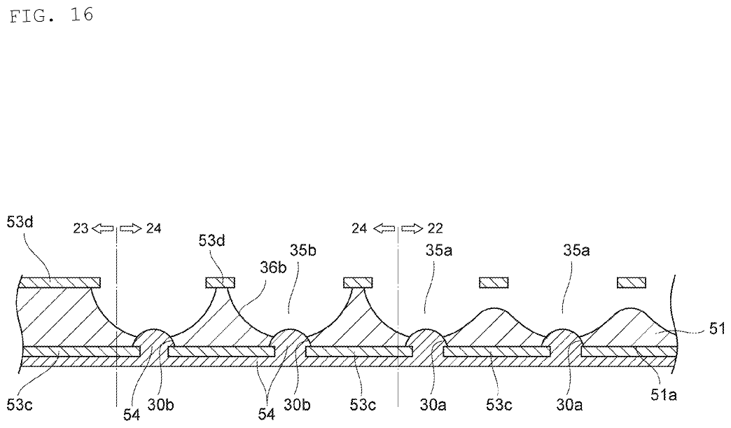

The second top part 32b that may be disposed in the dummy region 24 may be a top part remaining unetched as shown in FIG. 16. In other words, the second surface 51b of the metal plate 51 may be left between adjacent two of the fourth recesses 35b on the second surface 20b in the dummy region 24. By fabricating the metal mask 20 such that the second top part 32b is left, the strength in the dummy region 24 is improved more, and the effective region 22 can be prevented from being deformed or broken.

The height H2 preferably may be 1.05 times the height H1 or more, may be 1.15 times or more, may be 1.25 times or more, may be 1.35 times or more, or may be 1.45 times or more. In addition, the height H2 preferably may be 4.25 times the height H1 or less, may be 4.00 times or less, may be 3.75 times or less, may be 3.50 times or less, or may be 3.25 times or less. The range of the height H2 with respect to the height H1 may be any combination of the above-described upper-limit values and lower-limit values, and for example, may be 1.05 times or more and 4.25 times or less, may be 1.05 times or more and 4.00 times or less, may be 1.15 times or more and 3.75 times or less, may be 1.25 times or more and 3.50 times or less, may be 1.35 times or more and 3.25 times or less, or may be 1.45 times or more and 3.25 times or less. When the height H2 is 1.05 times the height H1 or more, occurrence of breakage or a dent tends to be prevented more. When the height H2 is 4.00 times the height H1 or less, occurrence of a crinkle tends to be prevented more.

The height H2 preferably may be 0.40 times the height T or more, may be 0.45 times or more, may be 0.50 times or more, may be 0.55 times or more, or may be 0.60 times or more. In addition, the height H2 preferably may be 1.00 times the height T or less, may be 0.95 times or less, may be 0.90 times or less, may be 0.85 times or less, or may be 0.80 times or less.

The height H2 preferably may be 8.0 μm or more, may be 10.0 μm or more, may be 11.0 μm or more, may be 12.0 μm or more, or may be 13.0 μm or more. In addition, the height H2 preferably may be 32.5 μm or less, may be 30.0 μm or less, may be 27.5 μm or less, may be 25.0 μm or less, or may be 22.5 μm or less.

Increasing the height H2 as described above can prevent the effective region 22 from being deformed or broken. Note that the range of the height H2 may be determined by a combination of any one of the above-described plurality of lower-limit candidate values and any one of the above-described plurality of upper-limit candidate values.

Further, it is preferable that the height H2 close to the peripheral region 23 should be greater than the height H2 close to the effective region 22 on an identical straight line intersecting the dummy region 24 from the effective region 22 to the peripheral region 23. A great change in height between the first top part in the effective region 22 and the second top part in the dummy region 24 might cause local stress concentration on the portion with the great change in height. However, such a configuration that the height H2 in the dummy region 24 gradually increases toward the peripheral region 23 can relax the local stress concentration more. This prevents deformation and breakage of the effective region 22 more.

A method for measuring the height H1 and the height H2 will be described. First, a sample 20s for measuring the height H1 and the height H2 is collected from the effective region 22 and the dummy region 24 of the metal mask 20. Then, the height H1 and the height H2 can be measured by observing the sample 20s from the first surface 20a side with a scanning electron microscope or the like. Note that the height H1 and the height H2 are herein heights measured in the thickness direction of the metal mask starting from the first surface 20a. Then, the height H1 and the height H2 are measured based on the above-described method for a plurality of the samples 20s, and average values are calculated. The average values are used as the height H1 and the height H2.

It is preferable that the second angle θ2 should be smaller than the first angle θ1. This leads to the tendency that the effective region 22 can be prevented from being deformed or broken, and the utilization efficiency and vapor deposition accuracy of the vapor deposition material are improved more. The first angle θ1 may be adjusted by an etching amount when forming the second recess 35a from the second surface by etching or the like, for example.

The second angle θ2 preferably may be 1.60 times the first angle θ1 or less, may be 1.30 times or less, may be 1.00 times or less, may be 0.95 times or less, may be 0.90 times or less, or may be 0.85 times or less. In addition, the second angle θ2 preferably may be 0.30 times the first angle θ1 or more, may be 0.35 times or more, may be 0.40 times or more, may be 0.45 times or more, or may be 0.50 times or more.

The first angle θ1 preferably may be 30° or more, may be 35° or more, may be 40° or more, may be 45° or more, or may be 50° or more. In addition, the first angle θ1 preferably may be 80° or less, may be 75° or less, may be 70° or less, may be 65° or less, or may be 60° or less.

The second angle θ2 preferably may be 10° or more, may be 15° or more, may be 20° or more, may be 25° or more, may be 30° or more, or may be 35° or more. In addition, the second angle θ2 preferably may be 70° or less, may be 60° or less, may be 55° or less, or may be 50° or less.

Setting the first angle θ1 and the second angle θ2 as described above leads to the tendency that the effective region 22 can be prevented from being deformed or broken, and the utilization efficiency and vapor deposition accuracy of the vapor deposition material are improved more. Note that the above-described numeral ranges in relation to the first angle θ1 and the second angle θ2 may be determined by a combination of any one of the above-described plurality of lower-limit candidate values and any one of the above-described plurality of upper-limit candidate values.

It is preferable that the height H5 should be greater than the height H3. This leads to the tendency that the effective region 22 can be prevented from being deformed or broken, and the utilization efficiency and vapor deposition accuracy of the vapor deposition material are improved more. The height H5 may be adjusted by etching amounts of the first surface 20a and the second surface 20b, for example.

The height H5 preferably may be 0.90 times the height H3 or more, may be 1.00 times or more, may be 1.10 times or more, may be 1.20 times or more, or may be 1.30 times or more.

The height H3 preferably may be 0.01 times the height H5 or more, may be 0.05 times or more, may be 0.10 times or more, or may be 0.15 times or more. In addition, the height H3 preferably may be 1.10 times the height H5 or less, may be 1.00 times or less, may be 0.95 times or less, may be 0.90 times or less, may be 0.85 times or less, may be 0.80 times or less, may be 0.75 times or less, may be 0.70 times or less, may be 0.65 times or less, or may be 0.60 times or less. In addition, the range of the height H3 with respect to the height H5 may be any combination of the above-described upper-limit values and lower-limit values, and, for example, may be 0.01 times or more and 0.95 times or less, may be 0.05 times or more and 0.90 times or less, may be 0.10 times or more and 0.85 times or less, may be 0.10 times or more and 0.80 times or less, or may be 0.10 times or more and 0.75 times or less. When the height H5 is greater than the height H3, occurrence of breakage or a dent tends to be prevented more.

The height H3 preferably may be 0.10 times the height H1 or more, may be 0.15 times or more, may be 0.20 times or more, or may be 0.25 times or more. In addition, the height H3 preferably may be 0.70 times the height H1 or less, may be 0.60 times or less, may be 0.50 times or less, may be 0.45 times or less, or may be 0.40 times or less.

The height H3 preferably may be 0.1 μm or more, may be 0.3 μm or more, may be 0.5 μm or more, may be 0.7 μm or more, or may be 1.0 μm or more. In addition, the height H3 preferably may be 5.0 μm or less, may be 4.7 μm or less, may be 4.4 μm or less, may be 4.1 μm or less, may be 3.8 μm or less, or may be 3.5 μm or less.

The height H5 preferably may be 0.05 times the height H2 or more, may be 0.10 times or more, or may be 0.15 times or more. In addition, the height H5 preferably may be 0.70 times the height H2 or less, may be 0.60 times or less, may be 0.50 times or less, may be 0.45 times or less, may be 0.40 times or less, or may be 0.35 times or less.

The height H5 preferably may be 0.1 μm or more, may be 0.5 μm or more, may be 1.0 μm or more, may be 1.5 μm or more, or may be 2.0 μm or more. In addition, the height H5 preferably may be 12 μm or less, may be 10 μm or less, may be 8.0 μm or less, or may be 6.0 μm or less.

Setting the height H3 and the height H5 as described above leads to the tendency that the effective region 22 can be prevented from being deformed or broken, and the utilization efficiency and vapor deposition accuracy of the vapor deposition material are improved more. Note that the above-described numeral ranges in relation to the height H3 and the height H5 may be determined by a combination of any one of the above-described plurality of lower-limit candidate values and any one of the above-described plurality of upper-limit candidate values.

The method for manufacturing a metal mask according to one embodiment of the present disclosure includes a step of preparing the metal plate 51 including the first surface 51a and the second surface 51b positioned opposite to the first surface 51a, and an etching step of etching the metal plate 51 to form the metal mask 20. The metal mask 20 includes the effective region 22, the peripheral region 23, and the dummy region 24. The effective region 22 includes the first through-hole 25a and the first top part 32a. The first top part 32a has the height H1. The peripheral region 23 is positioned around the effective region 22. The dummy region 24 is positioned between the effective region 22 and the peripheral region 23. The dummy region 24 includes the second top part 32b. The second top part 32b has the height H2. The height H2 is greater than the height H1.

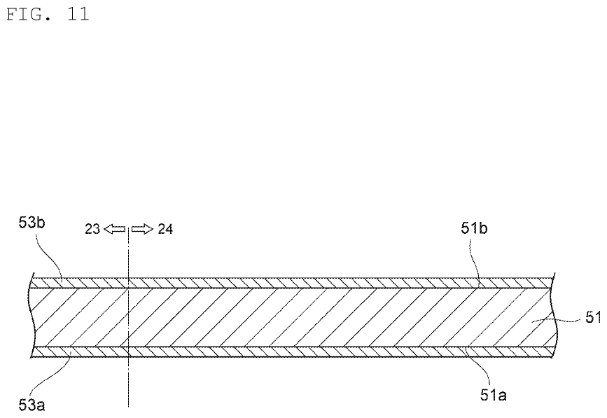

The method for manufacturing the metal mask 20 according to one embodiment of the present disclosure will be described mainly with reference to FIG. 10 to FIG. 16. FIG. 10 is a diagram showing a manufacturing apparatus 70 for manufacturing the metal mask 20 using the metal plate 51. First, a rolled-up body 50 including the metal plate 51 rolled up around a shaft member 52 is prepared. Subsequently, the metal plate 51 in the rolled-up body 50 is pulled out from the shaft member 52, and the metal plate 51 is sequentially transferred to a resist film forming device 71, an exposure and development device 72, an etching device 73, a film strip device 74, and a separation device 75 shown in FIG. 10. In the process, the through-holes 25 are formed in the metal plate 51, and further by cutting an elongated metal plate, the metal mask 20 formed of a sheet-like metal plate can be obtained.

Note that although FIG. 10 shows an example in which the metal plate 51 is transferred in its length direction to thereby move from device to device, the present disclosure is not limited to this. For example, the metal plate 51 provided with a resist film in the resist film forming device 71 may be rolled up again around the shaft member 52, and then the metal plate 51 in the state of the rolled-up body may be supplied to the exposure and development device 72. Alternatively, the metal plate 51 in a state provided with a resist film having subjected to exposure and development treatment in the exposure and development device 72 may be rolled up again around the shaft member 52, and then the metal plate 51 in the state of the rolled-up body may be supplied to the etching device 73. Alternatively, the metal plate 51 etched in the etching device 73 may be rolled up again around the shaft member 52, and then the metal plate 51 in the state of the rolled-up body may be supplied to the film strip device 74. Alternatively, the metal plate 51 from which a resin 54 which will be described later and the like have been removed in the film strip device 74 may be rolled up again around the shaft member 52, and then the metal plate 51 in the state of the rolled-up body may be supplied to the separation device 75.

The resist film forming device 71 forms a resist film on the surface of the metal plate 51. The exposure and development device 72 subjects the resist film to exposure treatment and development treatment, thereby patterning the resist film to form a resist pattern. The etching device 73 etches the metal plate 51 using the resist pattern as a mask to form the first through-holes 25a and the second through-holes 25b in the metal plate 51. The film strip device 74 strips a component provided for protecting portions of the metal plate 51 not to be etched, such as the resist pattern and the resin 54 which will be described later, against an etching solution. The separation device 75 performs a separation step of separating a portion of the metal plate 51 in which the first through-holes 25a and the second through-holes 25b corresponding to a single metal mask 20 have been formed from the metal plate 51. The metal mask 20 can be obtained in this manner.

In one embodiment of the present disclosure, a large number of the effective regions 22 are formed such that a plurality of the metal masks 20 can be fabricated from the metal plate 51. In other words, the plurality of metal masks 20 are allocated to the metal plate 51. For example, the large number of through-holes 25 may be formed in the metal plate 51 such that a plurality of the effective regions 22 are aligned in the width direction of the metal plate 51 and the effective regions 22 for the plurality of metal masks 20 are aligned in the length direction of the metal plate 51.

Hereinafter, each step of the method for manufacturing the metal mask 20 will be described in detail.

First, the rolled-up body 50 including the metal plate 51 rolled up around the shaft member 52 is prepared. The rolling method, the plating deposition method, or the like can be adopted as a method for fabricating the metal plate 51 having a desired thickness.

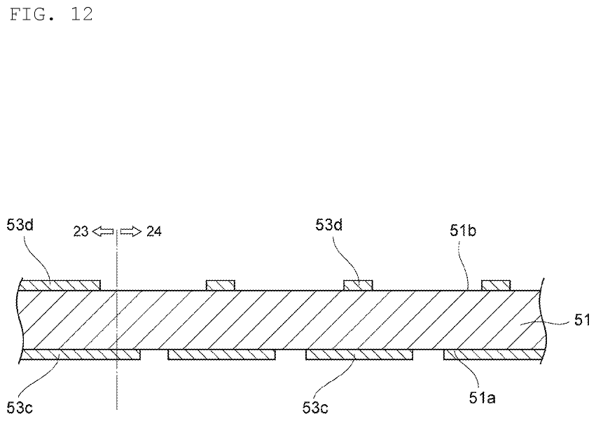

Subsequently, resist films 53a and 53b are formed as shown in FIG. 11 on the first surface 51a and the second surface 51b of the metal plate 51 pulled out from a pull-out device using the resist film forming device 71. The resist films 53a and 53b may be formed by bonding a dry film containing a photosensitive resist material such as an acrylic light curing resin, for example, onto the first surface 51a and the second surface 51b of the metal plate 51. Alternatively, the resist films 53a and 53b may be formed by, for example, coating the first surface 51a and the second surface 51b of the metal plate 51 with a coating solution containing a photosensitive resist material and drying the coating solution.

Although the resist films 53a and 53b may be of either a negative type or a positive type, the negative type is preferably used.

The thickness of the resist films 53a and 53b is 15 μm or less, for example, may be 10 μm or less, may be 6 μm or less, or may be 4 μm or less. In addition, the thickness of the resist films 53a and 53b is 1 μm or more, for example, may be 3 μm or more, may be 5 μm or more, or may be 7 μm or more. The range of the thickness of the resist films 53a and 53b may be determined by a combination of any one of the above-described plurality of upper-limit candidate values and any one of the above-described plurality of lower-limit candidate values.

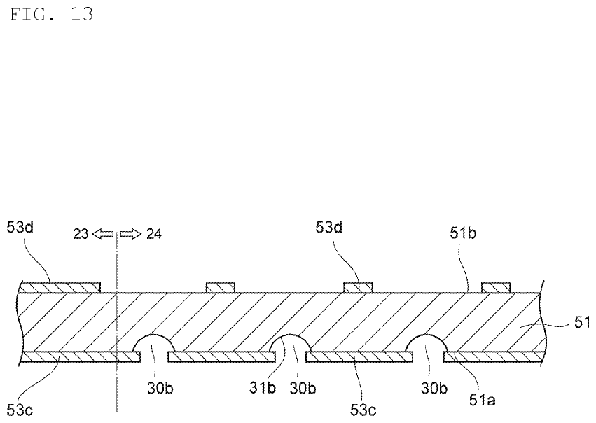

Subsequently, the resist films 53a and 53b are exposed and developed using the exposure and development device 72. This enables a first resist pattern 53c to be formed on the first surface 51a of the metal plate 51 and a second resist pattern 53d to be formed on the second surface 51b of the metal plate 51, as shown in FIG. 12. In the case of using the negative type resist films, for example, glass dry plates configured not to let light pass through to-be-moved regions of the resist films may be disposed on the resist films, so that the resist films may be exposed through the glass dry plates, and the resist films may further be developed.

Subsequently, the etching step of etching the metal plate 51 using the etching device 73 with the first resist pattern 53c and the second resist pattern 53d serving as masks to thereby form the metal mask 20 is performed. The etching step may include a first surface etching step and a second surface etching step.

First, the first surface etching step is performed as shown in FIG. 13. In the first surface etching step, regions of the first surface 51a of the metal plate 51 which are not covered by the first resist pattern 53c are etched using a first etching solution. For example, the first etching solution is sprayed from a nozzle disposed on the side facing the first surface 51a of the metal plate 51 being conveyed toward the first surface 51a of the metal plate 51 through the first resist pattern 53c. On this occasion, the second surface 51b of the metal plate 51 may be covered by a film resistant to the first etching solution or the like.

As a result of the first surface etching step, erosion by the first etching solution progresses in the regions of the metal plate 51 which are not covered by the first resist pattern 53c as shown in FIG. 13. A large number of the first recesses 30a and the third recesses 30b are thereby formed in the first surface 51a of the metal plate 51. A solution containing a ferric chloride solution and hydrochloric acid, for example, may be used as the first etching solution.

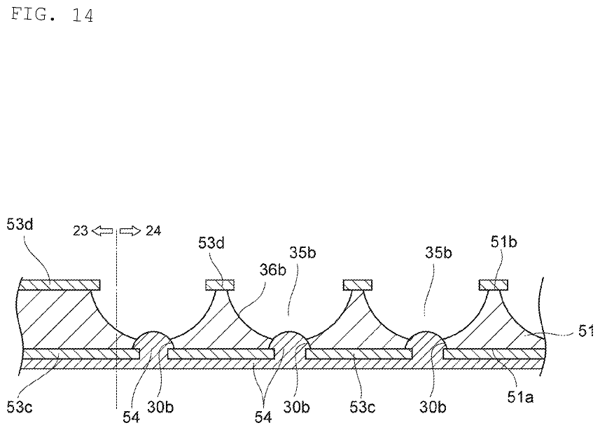

Next, the second surface etching step is performed as shown in FIG. 14. In the second surface etching step, regions of the second surface 51b of the metal plate 51 which are not covered by the second resist pattern 53d are etched using a second etching solution. The second recesses 35a and the fourth recesses 35b are thereby formed in the second surface 51b of the metal plate 51. The second surface 51b is etched until the first recess 30a and the second recess 35a communicate with each other so that the first through-holes 25a are formed accordingly. On this occasion, the third recess 30b and the fourth recess 35b may communicate with each other so that the second through-hole 25b may be formed. A solution containing a ferric chloride solution and hydrochloric acid, for example, may be used as the second etching solution, similarly to the above-described first etching solution. Note that when etching the second surface 51b, the first recesses 30 may be covered by the resin 54 resistant to the second etching solution as shown in FIG. 14.

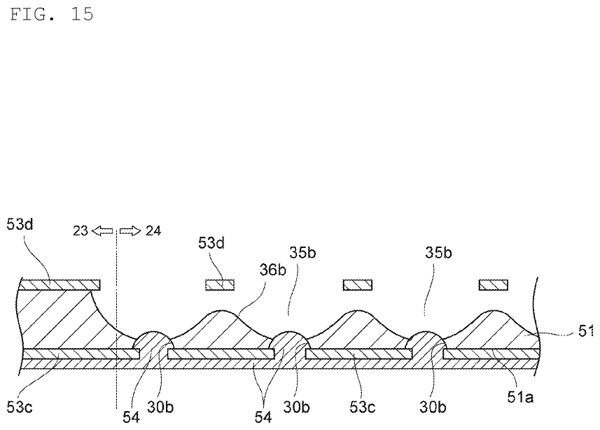

In the second surface etching step, etching may progress until adjacent two of the second recesses 35 are connected to each other as shown in FIG. 15. At the place where adjacent two of the second recesses 35a are connected to each other, the adjacent two second recesses 35a join together so that the ridge line 33 is spaced from the first resist pattern 53c, and erosion by etching proceeds on the ridge line 33a also in the thickness direction of the metal plate 51. The second resist pattern 53d is thereby stripped from the metal plate 51. Note that the second surface 51b may be partially left between adjacent two of the second recesses 35.

In the present disclosure, in the second surface etching step, etching may progress in the effective region 22 such that adjacent two of the second recesses 35a are connected to each other as shown in FIG. 15. In the dummy region 24, etching may progress such that adjacent two of the second recesses 35a are not connected to each other as shown in FIG. 14, or etching may progress such that adjacent two of the second recesses 35a are connected to each other as shown in FIG. 15.

This can facilitate making the height H2 of the second top part 32b that the dummy region 24 has greater than the height H1 of the first top part 32a that the effective region 22 has. In addition, the effective region 22 and the dummy region 24 may be formed simultaneously in the second surface etching step by adjusting the size and shape of holes in the second resist pattern 53d as shown in FIG. 16.

Next, a method for manufacturing an organic EL display device using the metal mask 20 according to the present embodiment will be described with reference to FIG. 2. The organic EL display device may include, in a stacked manner, the substrate 92 and a vapor deposition layer including the vapor deposition material 98 provided in a pattern shape. The method for manufacturing the organic EL display device includes a vapor deposition step of vapor-depositing the vapor deposition material 98 on a substrate such as the substrate 92 using the metal mask 20.

In the vapor deposition step, the metal mask device 10 is disposed first such that the metal mask 20 is opposed to the substrate. The metal mask 20 may be brought into close contact with the substrate 92 using a magnet. The inside of the vapor deposition device 90 may be brought into a vacuum atmosphere. Evaporating the vapor deposition material 98 in this state to fly to the substrate 92 via the metal mask 20 enables the vapor deposition material 98 to adhere to the substrate 92 in a pattern corresponding to the through-holes 25 of the metal mask 20.

The method for manufacturing the organic EL display device may include various steps in addition to the vapor deposition step of vapor-depositing the vapor deposition material 98 on the substrate such as the substrate 92 using the metal mask 20. For example, the method for manufacturing the organic EL display device may include a step of forming a first electrode on the substrate. The vapor deposition layer is formed on the first electrode. The method for manufacturing the organic EL display device may include a step of forming a second electrode on the vapor deposition layer. The method for manufacturing the organic EL display device may include a sealing step of sealing the first electrode, the vapor deposition layer, and the second electrode provided on the substrate 92.

The vapor deposition layer formed on the substrate such as the substrate 92 using the metal mask 20 is not limited to the above-described light emitting layer, but may include other layers. For example, the vapor deposition layer may include a hole injection layer, a hole transport layer, a light emitting layer, an electron transport layer, an electron injection layer, and the like in this order from the first electrode side. In this case, vapor deposition steps through use of the metal masks 20 corresponding to the respective layers may be performed respectively.

Note that the above-described embodiment can be modified variously. Hereinafter, modifications will be described with reference to the drawings according to necessity. In the following description and the drawings used in the following description, a portion that may be configured similarly to the above-described embodiment is denoted by a reference character identical to the reference character used for the corresponding portion in the above-described embodiment, and repeated description is omitted. In the case where the action and effect obtained in the above-described embodiment are clearly achieved also in the modifications, the description thereof is omitted in some cases.

### (Modifications)

As a first modification, the dummy region 24 may have blind recesses formed by half-etching or the like instead of the second through-holes 25b. FIG. 17 shows a perspective view of the dummy region 24 having blind recesses 25b′.

As a second modification, the step of forming the second recess 35 may be performed before the step of forming the first recess 30, or the step of forming the first recess 30 and the step of forming the second recess 35 may be performed in parallel.

As a third modification, laser light may be radiated to the inside of the first recess 30 or the second recess 35 using a laser designator, thereby causing laser light to reach another surface of the metal plate 51 from the inside of the first recess 30 or the second recess 35 to form a through-hole.

As a fourth modification, the first through-hole 25a may have a circular or an elliptical shape, or may have another polygonal shape. An arrangement of the first through-holes 25a may also be lattice-shaped, or may be a diamond-shaped arrangement, or may be any other arrangement.

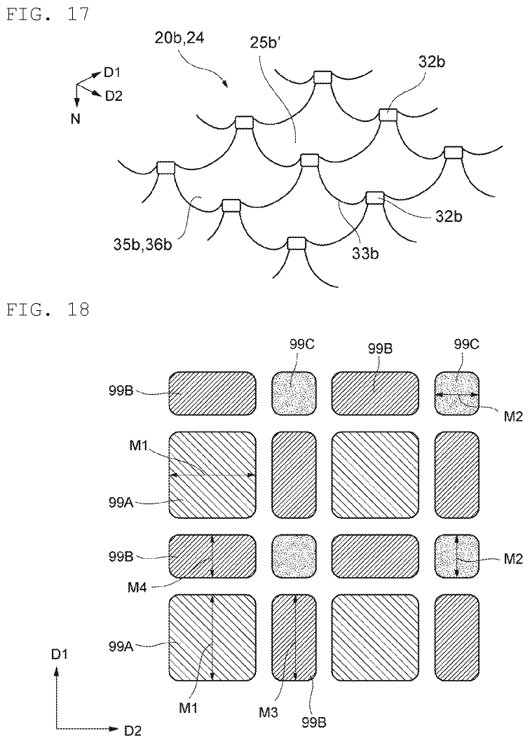

FIG. 18 shows another example of the arrangement of the first through-holes 25a. The arrangement shown in FIG. 18 has the first through-holes 25a having the long axis 26 parallel to the direction D1, and the first through-holes 25a having the long axis 26 parallel to the direction D2.

### Examples

Hereinafter, the present disclosure will be described more specifically using examples and comparative examples. The present disclosure is not limited at all by the following examples.

### Examples

Using the above-described method for manufacturing the metal mask, the first recesses and the second recesses were formed in the metal plate to manufacture the metal mask having the through-holes composed of the first recesses and the second recesses.

In this metal mask, the dummy region was formed around the effective region as shown in FIG. 3. On that occasion, the height H2 of the second top part that the dummy region had was made greater than the height H1 of the first top part in the effective region. An invar material was used as the metal plate to be a raw material of the metal mask.

### Comparative Examples

Metal masks were obtained similarly to the examples except that the height H2 of the second top part that the dummy region had was made smaller than the height H1 of the first top part in the effective region.

### (Evaluation)

Whether or not deformation or breakage had occurred in the metal mask until the metal mask was stretched over and welded to the frame since the metal mask manufacturing step was visually checked, and the result was described in Table 1. Note that as deformation occurred in the metal mask, a crinkle and a dent were recognized. Herein, a “dent” refers to a minute recess or bending that partially occurs until the metal mask is stretched over and welded to the frame since the metal mask manufacturing step. In addition, “breakage” refers to a fact that the metal mask is cut at a place such as the inside of the effective region or the border between the effective region and the peripheral region until the metal mask is stretched over and welded to the frame since the metal mask manufacturing step. Such deformation and breakage both may occur in a case where the metal mask is deficient in strength or when stress concentrates on a place having a low strength.

TABLE 1

| | Dummy Region | | | | | | | | | | | | | | | | |
|---|---|---|---|---|---|---|---|---|---|---|---|---|---|---|---|---|---|
| | The | | | | | Effective Region | | | | | | | | | | | |
| | number | | H2/ | | | | H1/ | | | | | H2/ | H5/ | H3/ | H3/ | H5/ | |
| | of rows | H2 | T | θ₂ | H5 | H1 | T | θ₁ | H3 | T | θ₂/θ₁ | H1 | H3 | H5 | H1 | H2 | Defect |
| Unit | row | [μm] | — | [°] | [μm] | [μm] | — | [°] | [μm] | [μm] | — | — | — | — | — | — | — |
| Example 1 | 3 | 13.1 | 0.66 | 45.0 | 5.5 | 12.0 | 0.60 | 46.2 | 4.7 | 20 | 0.98 | 1.09 | 1.17 | 0.85 | 0.39 | 0.42 | n/a |
| Example 2 | 2 | 14.0 | 0.56 | 41.2 | 4.1 | 11.0 | 0.44 | 47.7 | 3.1 | 25 | 0.86 | 1.27 | 1.32 | 0.76 | 0.28 | 0.29 | n/a |
| Example 3 | 2 | 13.5 | 0.54 | 44.0 | 4.4 | 6.9 | 0.28 | 60.4 | 1.9 | 25 | 0.73 | 1.96 | 2.32 | 0.43 | 0.28 | 0.33 | n/a |
| Example 4 | 3 | 25.0 | 0.83 | 24.4 | 3.1 | 8.0 | 0.27 | 59.8 | 2.2 | 30 | 0.41 | 3.13 | 1.41 | 0.71 | 0.28 | 0.12 | n/a |
| Example 5 | 3 | 31.1 | 0.78 | 20.3 | 3.9 | 7.9 | 0.20 | 60.0 | 2.1 | 40 | 0.34 | 3.94 | 1.86 | 0.54 | 0.27 | 0.13 | n/a |
| Comparative | 2 | 8.9 | 0.45 | 52.7 | 2.3 | 10.1 | 0.51 | 49.8 | 2.8 | 20 | 1.06 | 0.88 | 0.82 | 1.22 | 0.28 | 0.26 | breakage |
| Example 1 | | | | | | | | | | | | | | | | | |
| Comparative | 2 | 9.1 | 0.36 | 52.8 | 3.3 | 8.9 | 0.36 | 56.3 | 3.8 | 25 | 0.94 | 1.02 | 0.87 | 1.15 | 0.43 | 0.36 | dent |
| Example 2 | | | | | | | | | | | | | | | | | |
| Comparative | 2 | 35.0 | 0.70 | 17.9 | 15.0 | 8.1 | 0.16 | 42.7 | 1.1 | 50 | 0.42 | 4.32 | 13.64 | 0.07 | 0.14 | 0.43 | crinkle |
| Example 3 | | | | | | | | | | | | | | | | | |

As shown in Table 1, the metal masks of the examples included the predetermined dummy region, so that the boundary portion between the effective region and the peripheral region was improved in strength. As a result, deformation, breakage, or the like was not identified in the metal masks until each of the metal mask was stretched over and welded to the frame since the metal mask manufacturing step.

On the other hand, it was found that in the comparative examples without including the predetermined dummy region, deformation such as a dent or a crinkle, and besides, breakage or the like occurred in the metal masks. The reason is considered that in the comparative examples without including the predetermined dummy region, stress concentrated on the boundary portion between the effective region and the peripheral region because of the difference in strength between the effective region and the peripheral region, which resulted in deformation and breakage. However, the reason is not limited to this.

When the height H2 is 1.05 times the height H1 or more, the strength in the dummy region is improved more, which can prevent the effective region from being deformed or broken. Further, when the height H2 is 4.00 times the height H1 or less, stress can be prevented from concentrating on a place having an extremely low strength, which leads to the tendency that occurrence of a crinkle is prevented more.

Furthermore, when the height H5 is greater than the height H3, the strength in the dummy region is improved more, which can prevent the effective region from being deformed or broken. In addition, when the height H5 is a predetermined value or less with respect to the height H3, stress can be prevented from concentrating on a place having an extremely low strength, which leads to the tendency that occurrence of a crinkle is prevented more.

### INDUSTRIAL APPLICABILITY

The metal mask of the present invention has industrial applicability as a metal mask to be used for manufacturing an organic EL display device, and the like.

1. A metal mask including an effective region, a peripheral region, and a dummy region, wherein
the effective region includes a first through-hole and a first top part,
the first top part has a height H1,
the peripheral region is positioned around the effective region,
the dummy region is positioned between the effective region and the peripheral region,
the dummy region includes a second top part,
the second top part has a height H2, and
the height H2 is greater than the height H1.

2. The metal mask according to claim 1, wherein the dummy region is a region equal to a range having two or more rows and five or less rows of the second top parts.

3. The metal mask according to claim 1, wherein the height H2 close to the peripheral region is greater than the height H2 close to the effective region on an identical straight line intersecting the dummy region from the effective region to the peripheral region.

4. The metal mask according to claim 1, wherein the height H2 is 1.05 times the height H1 or more and 4.00 times the height H1 or less.

5. The metal mask according to claim 1, wherein
the metal mask includes a first surface and a second surface positioned opposite to the first surface,
the dummy region includes a second through-hole,
the first through-hole has a first recess on the first surface side, and a second recess, a first connection part, and a first angle θ1 on the second surface side,
the first connection part is a ridge part where the first recess and the second recess are connected to each other,
the first angle θ1 is an angle made by a straight line K1 with respect to a thickness direction N of the metal mask, the straight line K1 passing through a portion P1a of the first connection part closest to the first top part and a portion P2a of the first top part closest to the first connection part,
the second through-hole has a third recess on the first surface side, and a fourth recess, a second connection part, and a second angle θ2 on the second surface side,
the second connection part is a ridge part where the third recess and the fourth recess are connected to each other,
the second angle θ2 is an angle made by a straight line K2 with respect to the thickness direction N of the metal mask, the straight line K2 passing through a portion P1b of the second connection part closest to the second top part and a portion P2b of the second top part closest to the second connection part, and
the second angle θ2 is smaller than the first angle θ1.

6. The metal mask according to claim 1, wherein
the metal mask includes a first surface and a second surface positioned opposite to the first surface,
the dummy region includes a second through-hole,
the first through-hole has a first recess on the first surface side, and a second recess, a first connection part, and a height H3 on the second surface side,
the first connection part is a ridge part where the first recess and the second recess are connected to each other,
the height H3 is a height from the first surface to the first connection part,
the second through-hole has a third recess on the first surface side, and a fourth recess, a second connection part, and a height H5 on the second surface side,
the second connection part is a ridge part where the third recess and the fourth recess are connected to each other,
the height H5 is a height from the first surface to the second connection part, and
the height H5 is greater than the height H3.

7. The metal mask according to claim 5, wherein
the first through-hole has the height H3 and a height H4,
the height H3 is a height from the first surface to the first connection part,
the height H4 is a height from the second surface to the first connection part, and
the height H3 is smaller than the height H4.

8. The metal mask according to claim 1, wherein the dummy region includes a top part remaining unetched.

9. A method for manufacturing a metal mask, comprising:
a step of preparing a metal plate including a first surface and a second surface positioned opposite to the first surface; and
an etching step of etching the metal plate to form the metal mask, wherein
the metal mask includes an effective region, a peripheral region, and a dummy region,
the effective region includes a first through-hole and a first top part,
the first top part has a height H1,
the peripheral region is positioned around the effective region,
the dummy region is positioned between the effective region and the peripheral region,
the dummy region includes a second top part,
the second top part has a height H2, and
the height H2 is greater than the height H1.
